(19) United States
(12) Patent Application Publication
(10) Pub. No.: US 2026/0338850 A1
(43) Pub. Date: Oct. 29, 2026

(54) METHOD FOR PREDICTING ELECTRICAL CHARACTERISTICS OF SEMICONDUCTOR ELEMENT

(71) Applicant: SEMICONDUCTOR ENERGY LABORATORY CO., LTD., Atsugi-shi (JP)

(72) Inventors: Seiko INOUE, Atsugi (JP); Yusuke KOUMURA, Atsugi (JP); Takahiro FUKUTOME, Atsugi (JP)

(21) Appl. No.: 19/404,507

(22) Filed: Dec. 1, 2025

Related U.S. Application Data
(63) Continuation of application No. 17/611,987, filed on May 11, 2020, now abandoned.

(30) Foreign Application Priority Data
May 23, 2019 (JP) 2019-096919

(51) Int. Cl. G01R 31/26; G01R 31/28; G06N 3/045; H10D 30/67; H10P 74/20

(52) U.S. Cl. CPC G01R 31/26; G01R 31/2832; G06N 3/045; H10D 30/6755; H10P 74/207

(57) ABSTRACT

The electrical characteristics of a semiconductor element are predicted from a process list. The first learning model includes a step of learning the process list for generating the semiconductor element and a step of generating a first feature value. The second learning model includes a step of learning the electrical characteristics of the semiconductor element generated in accordance with the process list and a step of generating a second feature value. The third learning model includes a step of performing multimodal learning with use of the first feature value and the second feature value and a step of outputting a value of a variable used in a formula for the semiconductor element characteristics. The first to third learning models include neural networks different from each other.

### CROSS REFERENCE TO RELATED APPLICATIONS

This application is a continuation of U.S. application Ser. No. 17/611,987, filed Nov. 17, 2021, now pending, which is incorporated by reference, and claims the benefit of a U.S. National Phase Application under 35 U.S.C. § 371 of International Application PCT/IB2020/054411, filed on May 11, 2020, which is incorporated by reference and claims the benefit of a foreign priority application filed in Japan on May 23, 2019, as Application No. 2019-096919.

### TECHNICAL FIELD

One embodiment of the present invention relates to a method for learning a multimodal learning model using one or more of a process recipe, electrical characteristics, and image data. Another embodiment of the present invention relates to a method for predicting electrical characteristics of a semiconductor element with use of a multimodal learned model using one or more of a process recipe, electrical characteristics, and image data. Another embodiment of the present invention relates to a method for predicting electrical characteristics of a semiconductor element with use of a computer.

Note that a semiconductor element in this specification and the like refers to every element that can operate by utilizing semiconductor characteristics. Examples thereof are semiconductor elements such as a transistor, a diode, a light-emitting element, and a light-receiving element. Another example of a semiconductor element is a passive element, such as a capacitor, a resistor, or an inductor, which is formed using a conductive film or an insulating film. Still another example of a semiconductor element is a semiconductor device provided with a circuit including a semiconductor element or a passive element.

### BACKGROUND ART

In recent years, a novel semiconductor element has been developed to resolve an issue such as an increase in computational complexity or an increase in power consumption, in a field using artificial intelligence (AI), a field of robots, or a field needing high power energy for power ICs or the like. Integrated circuits demanded by markets or semiconductor elements used in the integrated circuits have been becoming more complicated; meanwhile, an early startup of integrated circuits having novel functions has been demanded. Note that for the process design, device design or circuit design in the development of semiconductor elements, knowledge, know-how, experience, or the like of skilled engineers is required.

In recent years, parameter adjustment of a transistor physical model by using genetic algorithm has been known. Patent Document 1 discloses a parameter adjustment device in which genetic algorithm is used for parameter adjustment of a transistor physical model.

### PRIOR ART

### Patent Document

[Patent Document 1] Japanese Published Patent Application No. 2005-38216

### SUMMARY OF THE INVENTION

### Problems to be Solved by the Invention

The process design, the device design, and the circuit design are necessary to develop a semiconductor element. In formation of a semiconductor element, the semiconductor element is formed by combination of a plurality of processing steps. There is a problem that electric characteristics of the semiconductor element vary when the order of processing steps is changed. There is also a problem, in semiconductor elements formed even with the same steps, that electric characteristics differ when manufacturing equipment or process conditions differ between the semiconductor elements.

Moreover, even when semiconductor elements are formed with the same steps, different equipment having the same function, and the same conditions, there is a problem that the semiconductor devices exhibit different electrical characteristics along with the progress of scaling down. For example, the problem is, in some cases, attributed to the film-thickness accuracy of processing accuracy or manufacturing equipment and in, other cases, attributed to a physical model altered due to scaling down. To search for the cause, the time for a variety of experiments or evaluations is necessary, which raises a problem.

As described above, there are many factors affecting electrical characteristics of the semiconductor element, such as the order of processing steps, manufacturing equipment, process conditions, scaling down, the film-thickness accuracy and the processing accuracy; accordingly, it is extremely difficult to predict the electric characteristics of the semiconductor element with high accuracy.

In view of the above problems, an object of one embodiment of the present invention is to provide a simple method for predicting electrical characteristics of a semiconductor device. Another object of one embodiment of the present invention is to provide a simple method for predicting electrical characteristics of a semiconductor element with use of a computer. Another object of one embodiment of the present invention is to provide a neural network that learns a process list of a semiconductor element and outputs a first feature value. Another object of one embodiment of the present invention is to provide a neural network that learns electrical characteristics of a semiconductor element generated in accordance with the process list of the semiconductor element and outputs a second feature value. Another object of one embodiment of the present invention is to provide a neural network that learns a schematic cross-sectional view or a cross-sectional observation image of a semiconductor element generated in accordance with the process list of the semiconductor element and outputs a third feature value. Another object of one embodiment of the present invention is to provide a neural network that performs multimodal learning with use of the first to third feature values. Another object of one embodiment of the present invention is that a neural network performing multimodal learning outputs a value of a variable used in a formula representing electrical characteristics of a semiconductor element.

Note that the description of these objects does not preclude the existence of other objects. One embodiment of the present invention does not have to achieve all these objects. Other objects are apparent from and can be derived from the description of the specification, the drawings, the claims, and the like.

### Means for Solving the Problems

One embodiment of the present invention is a method for predicting electrical characteristics of a semiconductor element including a feature-value calculation portion and a feature prediction portion. The feature-value calculation portion includes a first learning model and a second learning model, and the feature prediction portion includes a third learning model. The method for predicting electrical characteristics of a semiconductor element includes a step of learning a process list for generating the semiconductor element, in the first learning model; a step of generating a first feature value in the first learning model; a step of learning electrical characteristics of the semiconductor element generated in accordance with the process list, in the second learning model; a step of generating a second feature value in the second learning model; a step of performing multimodal learning, in the third learning model, with use of the first feature value and the second feature value; and includes a step of outputting a value of a variable used in a formula representing the electrical characteristics of the semiconductor element, from the third learning model.

In the above structure of the method for predicting electrical characteristics of a semiconductor element, the feature-value calculation portion preferably includes a fourth learning model. The method includes a step of learning a schematic cross-sectional view generated using the process list, in the fourth learning model; a step of generating a third feature value in the fourth learning model; a step of performing multimodal learning in the third learning model with use of the first feature value, the second feature value, and the third feature value; and a step of outputting the value of the variable used in the formula representing the electrical characteristics of the semiconductor element, from the third learning model.

In the above structure of the method for predicting electrical characteristics of a semiconductor element, the first learning model preferably includes a first neural network, and the second learning model preferably includes a second neural network. The method preferably includes a step of updating a weight coefficient of the second neural network by the first feature value generated by the first neural network.

In the above structure of the method for predicting electrical characteristics of a semiconductor element, when the first learning model is supplied with a process list for inference and the second learning model is supplied with a value of a voltage applied to a terminal of the semiconductor element, the method preferably includes a step of outputting a value of current corresponding to the value of the voltage, from the second learning model.

In the above structure of the method for predicting electrical characteristics of a semiconductor element, when the first learning model is supplied with a process list for inference and the second learning model is supplied with a value of a voltage applied to a terminal of the semiconductor element, the method preferably includes a step of outputting the value of the variable used in the formula for the electrical characteristics of the semiconductor element, from the third learning model.

In the above structure of the method for predicting electrical characteristics of a semiconductor element, the semiconductor element is preferably a transistor. Note that the transistor preferably includes a metal oxide in a semiconductor layer.

### Effect of the Invention

According to one embodiment of the present invention, a simple method for predicting electrical characteristics of a semiconductor element can be provided. According to another embodiment of the present invention, a simple method for predicting electrical characteristics of a semiconductor element with use of a computer can be provided. According to another embodiment of the present invention, a neural network that learns a process list of a semiconductor element and outputs a first feature value can be provided. According to another embodiment of the present invention, a neural network that learns electrical characteristics of a semiconductor element generated in accordance with the process list of the semiconductor element and outputs a second feature value can be provided. According to another embodiment of the present invention, a neural network that learns a schematic cross-sectional view or a cross-sectional image of a semiconductor element generated in accordance with the process list of the semiconductor element and outputs a third feature value can be provided. According to another embodiment of the present invention, a neural network that performs multimodal learning with use of the first to third feature values can be provided. According to another embodiment of the present invention, a neural network that performs multimodal learning can output a value of a variable used in a formula representing electrical characteristics of a semiconductor element.

Note that the effects of one embodiment of the present invention are not limited to the effects listed above. The effects listed above do not preclude the existence of other effects. Note that the other effects are effects that are not described in this section and will be described below. The effects that are not described in this section are derived from the descriptions of the specification, the drawings, and the like and can be extracted from these descriptions by those skilled in the art. Note that one embodiment of the present invention is to have at least one of the effects listed above and/or the other effects. Accordingly, depending on the case, one embodiment of the present invention does not have the effects listed above in some cases.

### BRIEF DESCRIPTION OF THE DRAWINGS

FIG. 1 is a diagram showing a method for predicting electrical characteristics of a semiconductor element.

FIG. 2A, FIG. 2B, FIG. 2C, and FIG. 2D are each a table showing a process list.

FIG. 3A and FIG. 3B are diagrams each showing a process list. FIG. 3C is a diagram showing a neural network that learns the process list.

FIG. 4A and FIG. 4B are diagrams each showing electrical characteristics of a semiconductor element. FIG. 4C is a diagram showing a neural network that learns the electrical characteristics.

FIG. 5 is a diagram showing a method for predicting electrical characteristics of a semiconductor element.

FIG. 6A is a diagram showing a neural network that learns image data. FIG. 6B is a schematic cross-sectional view of a semiconductor element. FIG. 6C is a cross-sectional observation image of the semiconductor element.

FIG. 7 is a diagram showing a method for predicting electrical characteristics of a semiconductor element.

FIG. 8 is a diagram showing a method for predicting electrical characteristics of a semiconductor element.

FIG. 9 is a diagram showing a computer for activating a program.

### MODE FOR CARRYING OUT THE INVENTION

Embodiment is described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be interpreted as being limited to the descriptions of the embodiment below.

Note that in structures of the invention described below, the same portions or portions having similar functions are denoted by the same reference numerals in different drawings, and a description thereof is not repeated. Furthermore, the same hatch pattern is used for the portions having similar functions, and the portions are not especially denoted by reference numerals in some cases.

In addition, the position, size, range, or the like of each structure shown in drawings does not represent the actual position, size, range, or the like in some cases for easy understanding. Therefore, the disclosed invention is not necessarily limited to the position, size, range, or the like disclosed in the drawings.

Furthermore, it is noted that ordinal numbers such as “first”, “second”, and “third” used in this specification are used in order to avoid confusion among components, and the terms do not limit the components numerically.

### Embodiment

In one embodiment of the present invention, a method for predicting electrical characteristics of a semiconductor element will be described. For the method for predicting electrical characteristics of a semiconductor element, a feature-value calculation portion and a feature prediction portion are used as an example. The feature-value calculation portion includes a first learning model and a second learning model, and the feature prediction portion includes a third learning model. The first learning model includes a first neural network, the second learning model includes a second neural network, and the third learning model includes a third neural network. Note that the first to third neural networks are preferably different from each other.

First, a learning method for predicting electrical characteristics of a semiconductor element will be described.

As an example, the case where the first learning model learns a process list for generating a semiconductor element is described. The first learning model is supplied with the process list for generating a semiconductor element, thereby updating a weight coefficient of the first neural network. In other word, the first neural network is a neural network performing learning using the process list as teacher data. Hereinafter, a semiconductor element is, for example, represented as a transistor in the description. Note that the semiconductor element is not limited to a transistor. The transistor is just an example, and the semiconductor element may be a diode, a thermistor, a gyroscope sensor, an acceleration sensor, a light-emitting element, a light-receiving element, or the like. Note that a semiconductor element can include a resistor, a capacitor, or the like.

Note that the above-described process list corresponds to information that is a combination of a plurality of steps needed to form a transistor. Next, one process item described in the process list is described. The process item preferably includes at least a process ID, an equipment ID, and conditions. The process includes at least one or a plurality of kinds of steps such as a film deposition step, a cleaning step, a resist application step, an exposure step, a development step, a shaping step, a baking step, a separation step, and a doping step. The conditions include setting conditions of equipment for each step and the like.

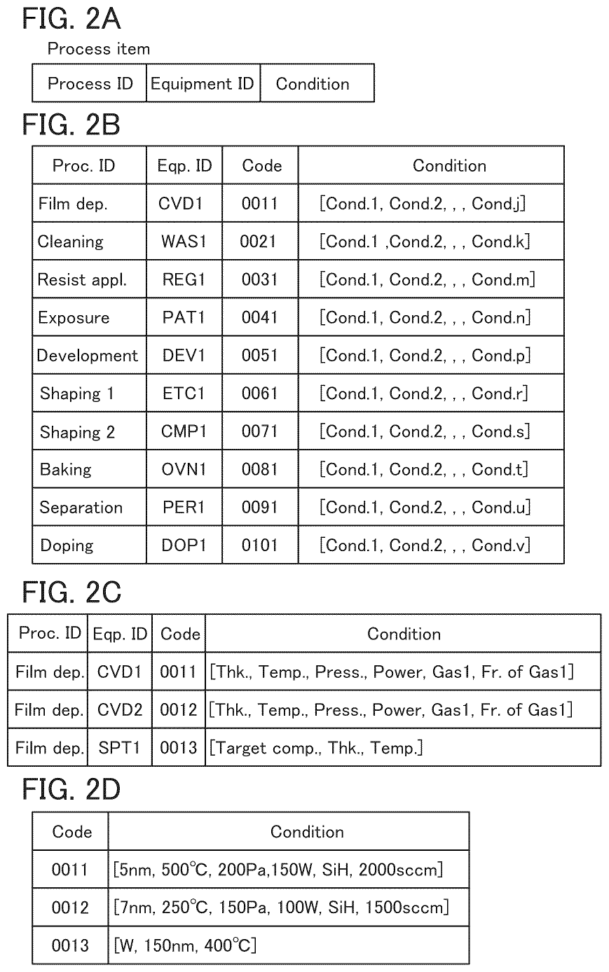

Each step listed as the process ID is conducted with equipment units with different functions in some cases. For example, in the film deposition step, a metal organic chemical vapor deposition method (MOCVD), a chemical vapor deposition method (CVD), a sputtering method, or the like is used. Thus, as the information supplied to the first learning model, the process ID and the equipment ID are represented as one code, whereby two-dimensional information can be managed as one-dimensional information. With use of the code representing the process ID and the equipment ID, the number of learning items is reduced, so that the computational complexity is reduced. Note that a method for generating a code is described in detail with reference to FIG. 2.

Furthermore, in the first learning model, a first feature value is generated by the first neural network which has done the learning according to the process list.

In one embodiment of the present invention, the second learning model performs learning of electrical characteristics of the transistor generated by the first model, concurrently with the learning in the first learning model. As a specific description, the second learning model performs learning of the electrical characteristics of the transistor generated in accordance with the process list supplied to the first learning model. The second learning model is supplied with the electrical characteristics of the transistor, thereby updating a weight coefficient of the second neural network. In other word, the second neural network is a neural network performing learning using the electrical characteristics of the transistor as teacher data. As the electrical characteristics of the transistor, for example, I_{d}-V_{gs} characteristics for evaluating the temperature characteristics, threshold voltage, or the like of the transistor and I_{d}-V_{ds} characteristics for evaluating the saturation characteristics of the transistor can be used.

The drain current I_{d} indicates the magnitude of current flowing, in the transistor, through a drain terminal at the time of applying voltages to a gate terminal, the drain terminal, and a source terminal. Note that the I_{d}-V_{gs} characteristics correspond to a change in drain current I_{d} caused by applying different voltages to the gate terminal of the transistor. The I_{d}-V_{ds} characteristics correspond to a change in values of drain current I_{d} caused by applying different voltages to the drain terminal of the transistor.

Furthermore, in the second learning model, a second feature value is generated by the second neural network which has done the learning of the electrical characteristics of the transistor generated in accordance with the process list.

Next, the third learning model performs multimodal learning with use of the first feature value and the second feature value. The third learning model is supplied with the first feature value and the second feature value, thereby updating a weight coefficient of the third neural network. In other word, the third neural network is a neural network performing learning using the process list and the electrical characteristics of the transistor corresponding to the process list as teacher data.

Note that the multimodal learning is learning using different types of information such as the first feature value generated from the process list for generating a semiconductor element and the second feature value generated from the electrical characteristics of the semiconductor element generated in accordance with the process list. For example, the neural network in which feature values generated from a plurality of different types of information are used as input information can be called a neural network having a multimodal interface. In this embodiment, the third neural network corresponds to a neural network having a multimodal interface.

For example, the third learning model outputs a value of a variable used in a formula representing the electrical characteristics of the transistor. In other words, the variable value is a value predicted by the method for predicting electrical characteristics of a semiconductor element.

For example, a formula of gradual channel approximation of the transistor is used as the formula representing the electrical characteristics of the transistor. Formula (1) represents electrical characteristics in a saturated region of the transistor. Formula (2) represents electric characteristics in a linear region of the transistor.

$$\begin{matrix}[ Formula 1 ] & \\ Id = μ FE \cdot Cox \cdot \frac{W}{L} \cdot [ \frac{{( V g - V th )}^{2}}{2} ] & ( 1 )\end{matrix}$$

$$\begin{matrix}[ Formula 2 ] & \\ Id = μ FE \cdot Cox \cdot \frac{W}{L} \cdot [ ( V g - V th ) V d - \frac{{V d}^{2}}{2} ] & ( 2 )\end{matrix}$$

Variables predicted by the method for predicting electrical characteristics of a transistor include a drain current I_{d}, a field-effect mobility μ_{FE}, a capacitance per unit area Cₒₓ of a gate insulating film, a channel length L, a channel width W, a threshold voltage Vₜₕ, or the like, used in Formula (1) or (2). It is preferable to give inference data described later to a gate voltage V_{g} applied to the gate terminal or a drain voltage Va applied to the drain terminal. The third learning model can output values of all variables described above or may output a value of any one or more of the variables.

Since supervised learning is used in the method for predicting electrical characteristics of a semiconductor element, the first to third neural networks are rewarded on the basis of the output result of the third learning model. For example, in order to approach the results calculated from Formula (1) or (2), the first to third neural networks update weight coefficients on the basis of the electrical characteristics of the transistor.

The feature-value calculation portion includes a fourth learning model. The fourth learning model learns a schematic cross-sectional view of a transistor generated in accordance with the process list. Alternatively, the fourth learning model learns a cross-sectional SEM image of a transistor generated in accordance with the process list. The fourth learning model generates a third feature value through the learning of the schematic cross-sectional view or the cross-sectional SEM image of the transistor. When the fourth learning model generates the third feature value, it is preferable that the first learning model and the second learning model respectively generate the first feature value and the second feature value, concurrently with the generation of the third feature value by the fourth learning model.

Thus, the third learning model performs multimodal learning with use of the first feature value, the second feature value, and the third feature value. Accordingly, the third learning model outputs a value of a variable used in a formula representing electrical characteristics of the transistor.

Furthermore, the first feature value updates a weight coefficient of the second neural network. The first feature value corresponds to an output of the first learning model that has done the learning of the process list. In other word, the first feature value has a relation with the electrical characteristics of the transistor generated in accordance with the process list.

Next, an inference method using the method for predicting electrical characteristics of a transistor is described. When the first learning model and the second learning model are respectively supplied with a process list for inference and a value of a voltage applied to a terminal of the semiconductor element, the third learning model outputs a value of a variable used in a formula representing the electrical characteristics of the transistor.

Furthermore, described is an inference method using the method for predicting electrical characteristics of a transistor in the case where the first feature value updates a weight coefficient of the second neural network. The first learning model is supplied with a process list for inference, and the second learning model is supplied with a value of a voltage applied to a terminal (a gate terminal, a drain terminal, or a source terminal) of the transistor. The second learning model outputs a value of current, as a predicted value, flowing through the drain terminal depending on the voltage value.

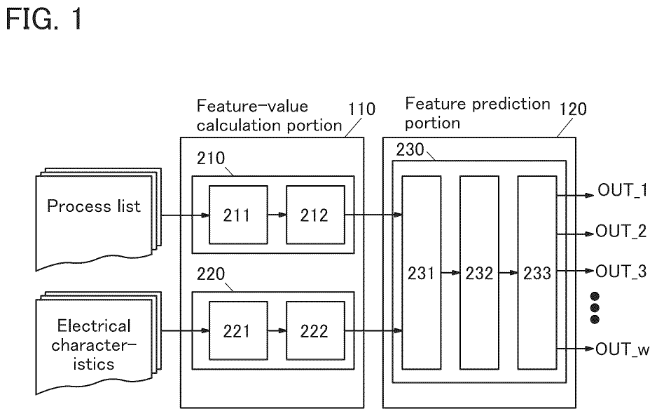

Next, a method for predicting electrical characteristics of a semiconductor element is described with reference to FIG. 1 to FIG. 8. Note that the description is made on the case where a transistor is used as the semiconductor element.

The method for predicting electrical characteristics of a transistor described with FIG. 1 includes a feature-value calculation portion 110 and a feature prediction portion 120. The feature-value calculation portion 110 includes a learning model 210 and a learning model 220. The feature prediction portion 120 includes a learning model 230.

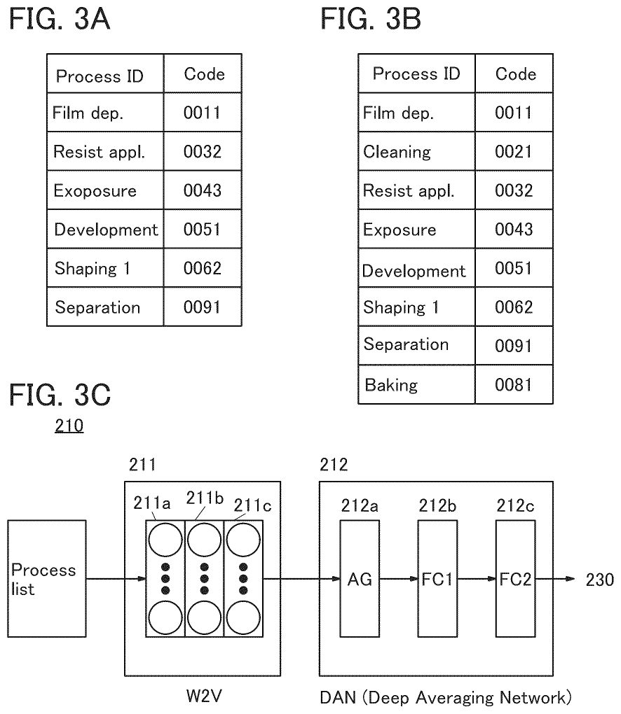

The learning model 210 includes a neural network 211 and a neural network 212. Note that the neural network 211 and the neural network 212 are described in detail with reference to FIG. 3C.

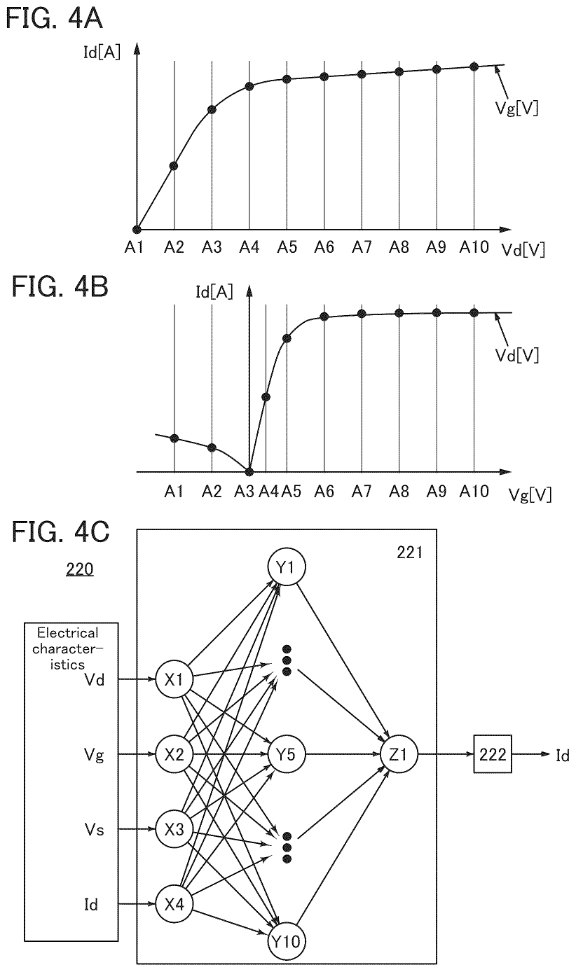

The learning model 220 includes a neural network 221 and an activation function 222. The neural network 221 preferably includes an input layer, an intermediate layer, and an output layer. Note that the neural network 221 is described in detail with reference to FIG. 4C.

The learning model 230 includes a neural network including a connected layer 231, a fully connected layer 232, and a fully connected layer 233. Note that the connected layer 231 includes a multimodal interface. In FIG. 1, the connected layer 231 couples the first feature value generated from the process list and the second feature value generated from the electrical characteristics of the transistor generated in accordance with the process list, thereby generating output data supplied to the fully connected layer 232.

The fully connected layer 233 outputs predicted values of electrical characteristics (e.g., drain current) to output terminals OUT_1 to OUT_w. The values of variables in Formula (1) or Formula (2) described above correspond to the output terminals OUT_1 to OUT_w. In the case where the semiconductor element is a resistor or a capacitor as another example, it is preferable to use a formula calculating a resistance value or a formula calculating the capacitance to obtain variable values output by the fully connected layer 233. Note that w is an integer greater than or equal to 1.

FIG. 2A to FIG. 2D are tables each showing a process list supplied to the learning model 210.

FIG. 2A is a table showing the minimum units of the process items in the process list. Note that the process list is composed of a plurality of process items. The process items include a process ID, an equipment ID, a setting condition of equipment, and the like. Although not illustrated in FIG. 2A, which portion in the transistor is formed by each process item may be written. Examples of process items in the process list include the process ID, the equipment ID, the condition, and the portion to be formed. Examples of portions to be formed include an oxide film, electrodes (such as a gate, a source, and a drain), and a semiconductor layer. In practical process for forming a semiconductor element, a plurality of steps, e.g., a step of forming a contact and a step of forming a wiring, are also included.

FIG. 2B illustrates an example of a table showing process items of a semiconductor element. Examples of the process ID include a film deposition step, a cleaning step, a resist application step, an exposure step, a development step, a shaping step 1, a shaping step 2, a baking step, a separation step, and a doping step. The equipment ID is preferably assigned to equipment used in each step. Note that the setting conditions of equipment in each step are preferably items set to equipment used in the corresponding step. When different equipment IDs are provided even for the same step, each equipment unit may be supplied with different setting condition.

The equipment ID used in the process can be assigned, for example, as follows: CVD1 assigned to the film deposition step, WAS1: the cleaning step, REGI: the resist application step, PAT1: the exposure step, DEV1: the development step, ETC1: the shaping step 1, CMP1: the shaping step 2, OVN1: the baking step, PER1: the separation step, and DOP1: the doping step. The process ID is preferably managed in association with the equipment ID constantly. The process ID and the equipment ID can be combined to be represented by one code. For example, when the process ID and the equipment ID are respectively the film deposition step and CVD1, the code is 0011. Note that a code to be assigned is managed as a unique number. In addition, the conditions set to each equipment unit include a plurality of setting items. In FIG. 2B, j, k, m, n, p, r, s, t, u, and v each denote an integer greater than or equal to 1.

FIG. 2C illustrates a table for description that different codes are assigned even for the same process item as long as equipment to be used differs. An example is given, in which there are a case where equipment employs a chemical vapor deposition method for film deposition or a case where equipment employs a sputtering method (equipment ID: SPT1) for film deposition even when the process IDs in both cases are the film deposition step. In addition, even in the film deposition using a chemical vapor deposition method, there are a case of equipment (equipment ID: CVD1) using plasma for film deposition and a case of equipment (equipment ID: CVD2) using heat for film deposition. As another example, when a plurality of same equipment units are included, a different code may be assigned to each unit. For example, in a factory possessing a plurality of equipment units for film deposition using plasma, the management of the unit numbers is necessary, even in the case where the equipment units have the same function, because the quality of films deposited differs in some cases. For example, the electrical characteristics of the transistor are affected by the equipment ID in the process list, in some cases.

FIG. 2D illustrates a table showing the process item included in the process list supplied to the learning model 210. As an example, a code representing the film deposition step, 0011, is described. The code 0011 means that the process ID is the deposition step and the equipment ID is CVD1. As shown in FIG. 2C, the film deposition conditions given to the code 0011 include a film thickness, a temperature, a pressure, a power, Gas 1, a flow rate of Gas 1, and the like. More specifically, the film deposition conditions given to the code 0011 are that the film thickness is 5 nm, the temperature: 500 °C, the pressure: 200 Pa, the power: 150 W, Gas 1: SiH, and the flow rate of Gas 1: 2000 sccm. It is preferable that the conditions that can be set as the process item be changed depending on equipment.

FIG. 3A and FIG. 3B are diagrams each showing a part of a process list. FIG. 3C is a diagram showing a neural network for learning the process list.

Steps for processing a film formed by a film deposition step are described, as an example, using the part of the process list shown in FIG. 3A. First, a film that is designated by the film deposition step is formed. Description of the film deposition conditions and the like is omitted for simplifying description. Equipment used in the film deposition step is found to be CVD1 from equipment ID to which the code 0011 is assigned. Note that for the description of the following steps, the drawings (e.g., FIG. 2B) are referred to, and description of conditions in each step is omitted.

Next, the deposited film is coated with a photoresist in a resist application step. Next, a mask pattern of the film is transferred to the photoresist in an exposure step. Next, the photoresist other than a portion to which the mask pattern is transferred is removed with a developer in a development step, so that a mask pattern of the photoresist is formed. A step of baking the photoresist may be included in the development step. Next, the film is shaped using the mask pattern formed in the photoresist in a shaping step 1. Next, the photoresist is separated in a separation step.

In FIG. 3B, a cleaning step is added after the film deposition step, and a baking step is added after the separation step, which is different from FIG. 3A. When the cleaning step is added after the film deposition step, for example, impurities remaining on the deposited film are removed, or an uneven upper surface of the film is uniformed. When the baking step is added after the separation step, impurities (such as an organic solvent or moisture) remaining on the film subjected to processing can be removed, or baking the film promotes a reaction of elements included in the film and enables a change in film quality. Note that baking the film causes an increase in the film density, thereby hardening the film.

Steps different from those in FIG. 3A are added, so that the film formed in the film deposition step in FIG. 3B have different characteristics. Therefore, the process list affects the electrical characteristics of a transistor generated in accordance with the process list.

FIG. 3C is a diagram showing the learning model 210 where the process list is learned as learning data. The learning model 210 includes the neural network 211 and the neural network 212.

Process items are given to the neural network 211 in the order of steps according to the process list. As shown in FIG. 2D, a step and equipment used in the step, which are the process items, are represented by one code. Each code is given a plurality of conditions set to equipment to be used. Each condition is denoted by a numeral or a numeral with a unit. To the neural network 211, a file listing a plurality of process items in the order of steps may be supplied.

For example, the neural network 211 preferably vectorizes the process items using Word2Vec (W2V). To vectorize text data, Word2VecGloVe (Global Vectors for Word Representation), Bag-of-words, or the like can be used. Vectorizing text data can be rephrased as conversion into distributed representation. Furthermore, distributed representation can be rephrased as embedded representation (feature vector or embedded vector).

In one embodiment of the present invention, the conditions of the process item are handled as not sentences but aggregates of words. Thus, it is preferable to handle the process list as aggregates of words. For example, the neural network 211 includes an input layer 211a, a hidden layer 211b, and a hidden layer 211c. The neural network 211 outputs a feature vector generated from the process list. At this point, a plurality of feature vectors can be output, or the vectors may be integrated to one. Hereinafter, the case where the neural network 211 outputs a plurality of feature vectors is described. Note that the hidden layer can include one or more hidden layers.

Next, the plurality of feature vectors generated by the neural network 211 are supplied to the neural network 212. For the neural network 212, it is preferable to use DAN (Deep Averaging Network). For example, the neural network 212 includes an AGGREGATE layer 212a, a fully connected layer 212b, and a fully connected layer 212c. The AGGREGATE layer 212a can collectively handle the plurality of feature vectors output from the neural network 211.

The fully connected layer 212b and the fully connected layer 212c preferably include a sigmoid function, a step function, a ramp function (Rectified Linear Unit), or the like as an activation function. A function with a nonlinear activation function is effective in feature vectorization of complicated leaning data. Thus, the neural network 212 can average the feature vectors of the process items constituting the process list and integrate them to one. The integrated feature vector is supplied to the learning model 230. The fully connected layer is, in some cases, one or more layers.

FIG. 4A and FIG. 4B are diagrams showing the electrical characteristics of a transistor generated in accordance with the process list that is used by the learning model 210 for learning. FIG. 4C is a diagram showing a neural network where the electrical characteristics of the transistor are learned.

FIG. 4A is a graph showing I_{d}-V_{ds} characteristics used to evaluate the saturation characteristics of the transistor. The I_{d}-V_{ds} characteristics show the current flowing through a drain terminal at the time when voltages are applied to a gate terminal, the drain terminal, and a source terminal of the transistor. In other words, the I_{d}-V_{ds} characteristics indicate a value of drain current, I_{d}, in a condition where the voltage applied to the drain terminal of the transistor varies. In FIG. 4A, the drain currents I_{d} at the time when a potential A1 to a potential A10 are supplied to the drain terminal of the transistor are plotted in the case where a fixed potential is supplied to the gate terminal of the transistor.

FIG. 4B is a graph showing I_{d}-V_{gs} characteristics used to evaluate linear characteristics of the transistor. The I_{d}-V_{gs} characteristics shows current flowing through the drain terminal at the time when voltages are applied to the gate terminal, the drain terminal, and the source terminal. In other words, the I_{d}-V_{gs} characteristics indicate a value of drain current, I_{d}, in a condition where the voltage applied to the gate terminal of the transistor varies. In FIG. 4B, the drain currents I_{d} at the time when the potential A1 to the potential A10 are supplied to the gate terminal of the transistor are plotted in the case where a fixed potential is supplied to the drain terminal of the transistor.

FIG. 4C is a diagram showing the neural network 221 where the electrical characteristics of the transistor are learned using data of FIG. 4A or FIG. 4B. In the neural network 221, for example, an input layer is supplied with a voltage Va applied to the drain terminal of the transistor, a voltage V_{g} applied to the gate terminal of the transistor, and a voltage Vs applied to the source terminal of the transistor. Furthermore, under the above-described conditions, the current I_{d} flowing through the drain terminal of the transistor may be supplied.

In the neural network 221, as an example, the input layer includes neurons X1 to X4, a hidden layer includes neurons Y1 to Y10, and an output layer includes a neuron Z1. The neuron Z1 performs feature vectorization of the electrical characteristics, and the activation function 222 outputs a predicted value. It is preferable that the number of neuron included in the hidden layer be equal to the number of plots supplied as learning data. It is further preferable that the number of neurons included in the hidden layer be larger than the number of plots supplied as learning data. In the case where the number of neurons included in the hidden layer is larger than the number of plots supplied as learning data, the learning model 220 learns the electrical characteristics of the transistor in detail. Note that the neuron Z1 has a function of the activation function 222.

As an example, a method with which the neural network 221 learns the electrical characteristics of the transistor is described. First, the neuron X1 is supplied with the voltage Va applied to the drain terminal of the transistor, the neuron X2 is supplied with the voltage V_{g} applied to the gate terminal of the transistor, the neuron X3 is supplied with the voltage Vs applied to the source terminal of the transistor, and the neuron X4 is supplied with the drain current I_{d} flowing through the drain terminal of the transistor. At this time, the drain current I_{d} is supplied as teacher data. A weight coefficient of the hidden layer is updated so that the output of the neuron Z1 or the output of the activation function 222 is close the drain current I_{d}. In the case where the drain current I_{d} is not supplied as learning data, learning is performed so that the output of the neuron Z1 or the output of the activation function 222 is close to the drain current I_{d}.

Although FIG. 4C shows an example in which the electrical characteristics of the transistor are sequentially supplied in accordance with plot points, all of the plot points may be concurrently supplied to the neural network 221. This is because the neural network 221 becomes able to perform calculation at high speed, which brings about an effect in shortening the development period of semiconductor elements.

The learning model 220 preferably performs learning concurrently with the learning in the learning model 210. A process list supplied to the learning model 210 is highly related to the electrical characteristics supplied to the learning model 220. Thus, concurrent learning in the learning model 220 and the learning model 210 is effective in learning for predicting the electrical characteristics of the transistor.

Next, the feature prediction portion 120 is described. For the description of the feature prediction portion 120, FIG. 1 is referred to. The feature prediction portion 120 includes the learning model 230. The learning model 230 is a neural network including the connected layer 231, the fully connected layer 232, and the fully connected layer 233. The fully connected layer is, in some case, one or more layers. The connected layer 231 couples feature vectors output from different learning models (the learning model 210 and the learning model 220) and integrates the coupled feature vectors to one feature vector. In other words, the feature prediction portion 120 provided with the connected layer 231 functions as a neural network including a multimodal interface.

The fully connected layer 233 outputs predicted values of the electrical characteristics to an output terminal OUT_1 to an output terminal OUT_w. In one embodiment of the present invention, the predicted values of the electrical characteristics as the outputs correspond to the field-effect mobility μ_{FE}, the capacitance per unit area Cₒₓ of a gate insulating film, the channel length L, the channel width W, the threshold voltage Vₜₕ, or the like in Formula (1) or (2) described above. In addition, it is preferable to output a drain voltage Va, a gate voltage V_{g}, or the like. Each value of variables calculated from the electrical characteristics of the transistor may be supplied to the connected layer 231 as teacher data. A weight coefficient of the learning model 230 is updated when the teacher data is supplied.

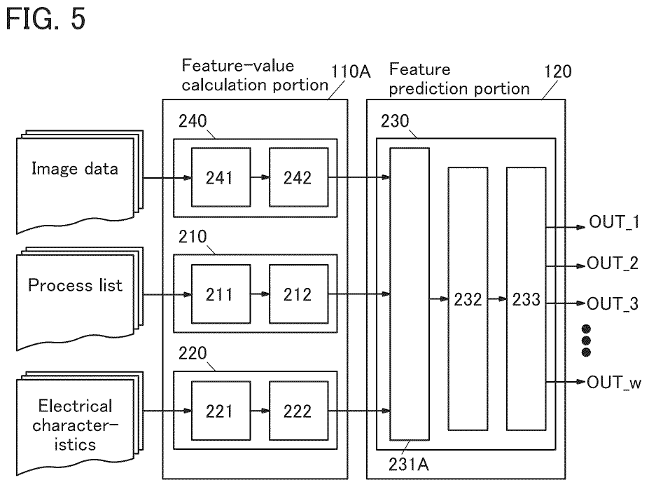

FIG. 5 is a diagram showing a method for predicting electrical characteristics of a semiconductor element, which is different from that in FIG. 1. FIG. 5 includes a feature-value calculation portion 110A including a learning model 240, which is different from the feature-value calculation portion 110 shown in FIG. 1. The learning model 240 is a neural network where image data is learned. The image data learned in the learning model 240 is a schematic cross-sectional view of a transistor formed in accordance with a process list or a cross-sectional observation image obtained with a scanning electron microscope (SEM).

A connected layer 231A included in the feature prediction portion 120 couples a feature vector generated from the process list, a feature vector generated from the electrical characteristics of the transistor generated in accordance with the process list, and a feature vector generated from the schematic cross-sectional view or a cross-sectional observation image of an actually produced device, and generates data output to the fully connected layer 232.

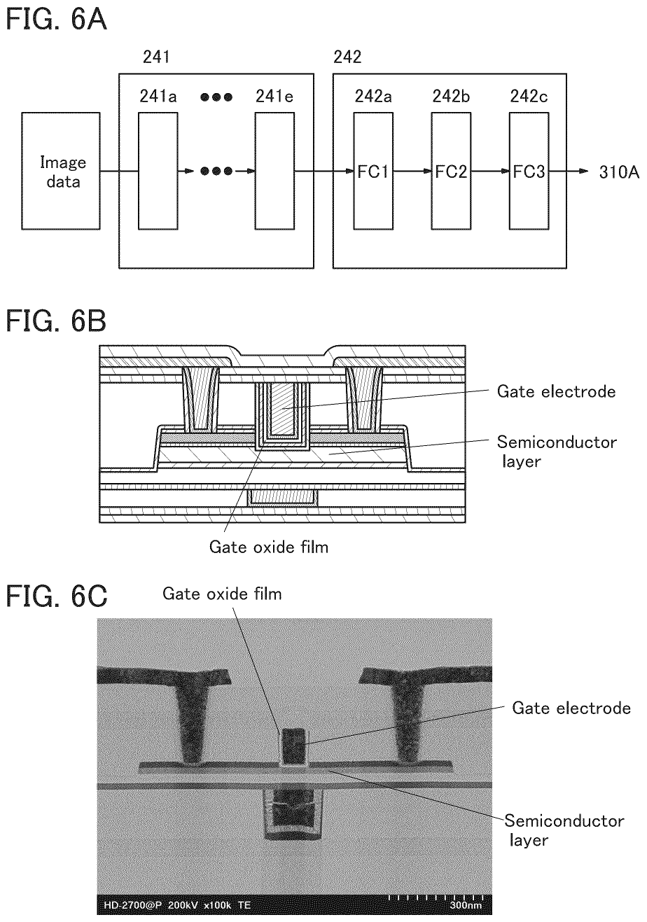

FIG. 6A is a diagram showing the learning model 240 in detail. The learning model 240 includes a convolutional neural network 241 and a fully connected layer 242. The convolutional neural network 241 includes a convolutional layer 241a to a convolutional layer 241e. The number of convolutional layers is not limited, and may be an integer greater than or equal to 1. FIG. 6A shows a case of including five convolutional layers as an example. The fully connected layer 242 includes a fully connected layer 242a to a fully connected layer 242c. Thus, the learning model 240 can be referred to as CNN (Convolutional Neural Network).

The feature-value calculation portion 110A provided with the learning model 240 facilitates the prediction of the electrical characteristics of a semiconductor element with use of different three feature vectors. FIG. 6B is a schematic cross-sectional view of a transistor, as an example of image data to be learned, generated in accordance with a process list supplied to the learning model 210. FIG. 6C is a cross-sectional observation image of the transistor generated in accordance with the process list supplied to the learning model 210. The learning model 240 for learning the schematic cross-sectional view of the transistor may be different from a learning model for learning the cross-sectional observation image of the transistor.

For example, a semiconductor layer, a gate oxide film, and a gate electrode are shown in FIG. 6B, and a semiconductor layer, a gate oxide film, and a gate electrode, which corresponds to those in FIG. 6C, are shown in FIG. 6C. In the cross-sectional observation image, the gate oxide film or the like of the transistor is sometimes difficult to recognize because it is a thin film. However, even a thin film, the misdetection of which may occur, is illustrated to be recognized in the schematic cross-sectional view. Thus, learning of the schematic cross-sectional view enables the cross-sectional observation image to be learned more accurately. The process list becomes more highly related to the electrical characteristics of the transistor and the actual cross-sectional observation image, whereby the prediction of the electrical characteristics of the semiconductor element becomes easy.

FIG. 6B and FIG. 6C each show an example of a transistor including a metal oxide in a semiconductor layer. The method for predicting electrical characteristics of a semiconductor element, which is one embodiment of the present invention, can also be applied to a transistor including silicon in a semiconductor layer. Furthermore, the method can be applied to a transistor including a compound semiconductor or an oxide semiconductor. Note that the semiconductor element is not limited to a transistor. The method for predicting electrical characteristics of a semiconductor element, which is one embodiment of the present invention, can also be applied to a resistor, a capacitor, a diode, a thermistor, a gyroscope sensor, an acceleration sensor, a light-emitting element, a light-receiving element, or the like.

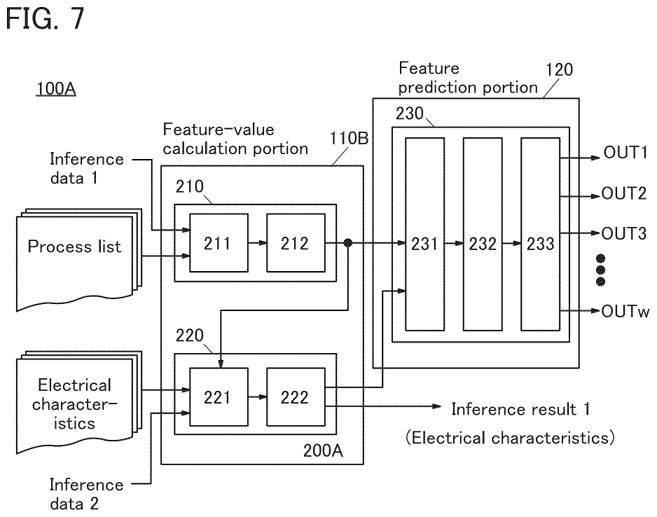

FIG. 7 is a diagram showing a method for predicting electrical characteristics of a semiconductor element, which is different from FIG. 1. A different point is that FIG. 7 includes a feature-value calculation portion 110B where an output of the learning model 210 updates a weight coefficient of the neural network 221. A feature vector of the process list is reflected in the weight coefficient of the neural network 221, whereby the neural network 221 enables the prediction of electrical characteristics of a transistor to be improved.

With reference to FIG. 7, a method for predicting electrical characteristics of a transistor, which uses the method for predicting electrical characteristics of a semiconductor element, is described. In the prediction of the electrical characteristics of the transistor, it is preferable that learning in each of the learning model 210, the learning model 220, and the learning model 230 has already been done. First, to the neural network 211, a process list with a new structure is supplied as inference data 1. To the neural network 221, a drain voltage, a gate voltage, and a source voltage respectively supplied to a drain terminal, a gate terminal, and a source terminal of the transistor are supplied as interference data 2.

With use of a feature vector generated by the inference data 1 and a feature vector generated by the inference data 2, the feature prediction portion 120 predicts each value of the variables in Formula (1) or (2) described above. The activation function 222 can output an inference result 1 based on the inference data 2. As the inference result 1, the drain current I_{d} can be predicted from the drain voltage, the gate voltage, and the source voltage respectively supplied to the drain terminal, the gate terminal, and the source terminal of the transistor.

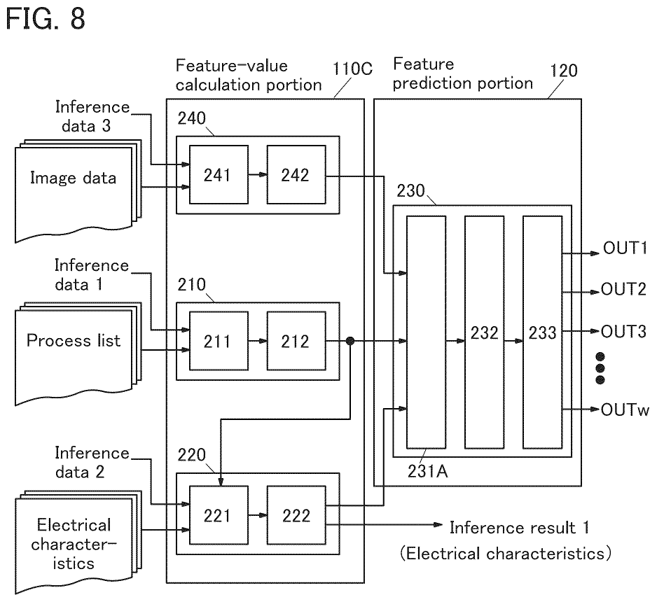

FIG. 8 is a diagram showing a method for predicting electrical characteristics of a semiconductor element, which is different from FIG. 5. FIG. 8 includes a feature-value calculation portion 110C where an output of the learning model 210 updates a weight coefficient of the neural network 221, which is different from the feature-value calculation portion 110A shown in FIG. 5.

With reference to FIG. 8, a method for predicting electrical characteristics of a transistor, which uses the method for predicting electrical characteristics of a semiconductor element, is described. In the prediction of the electrical characteristics of the transistor, it is preferable that learning in each of the learning model 210, the learning model 220, the learning model 230, and the learning model 240 has already been done. First, to the neural network 211, a process list with a new structure is supplied as inference data 1. To the neural network 221, a drain voltage, a gate voltage, and a source voltage respectively supplied to a drain terminal, a gate terminal, and a source terminal of the transistor are supplied as interference data 2. To the neural network 241, a schematic cross-sectional view or a cross-sectional observation image of the new structure is supplied as inference data 3.

With use of a feature vector generated by the inference data 1, a feature vector generated by the inference data 2, and a feature vector generated by the inference data 3, the feature prediction portion 120 predicts each value of the variables in Formula (1) or (2) described above. The activation function 222 can output an inference result 1 based on the inference data 2. As the inference result 1, the drain current I_{d} can be predicted from the drain voltage, the gate voltage, and the source voltage respectively supplied to the drain terminal, the gate terminal, and the source terminal of the transistor.

The fully connected layer 233 in FIG. 7 or FIG. 8 outputs predicted values of the electrical characteristics to the output terminal OUT_1 to the output terminal OUT_w. For example, in one embodiment of the present invention, the predicted values correspond to the field-effect mobility μ_{FE}, the capacitance per unit area Cₒₓ of a gate insulating film, the channel length L, the channel width W, the threshold voltage Vₜₕ, or the like in the Formula (1) or (2) described above.

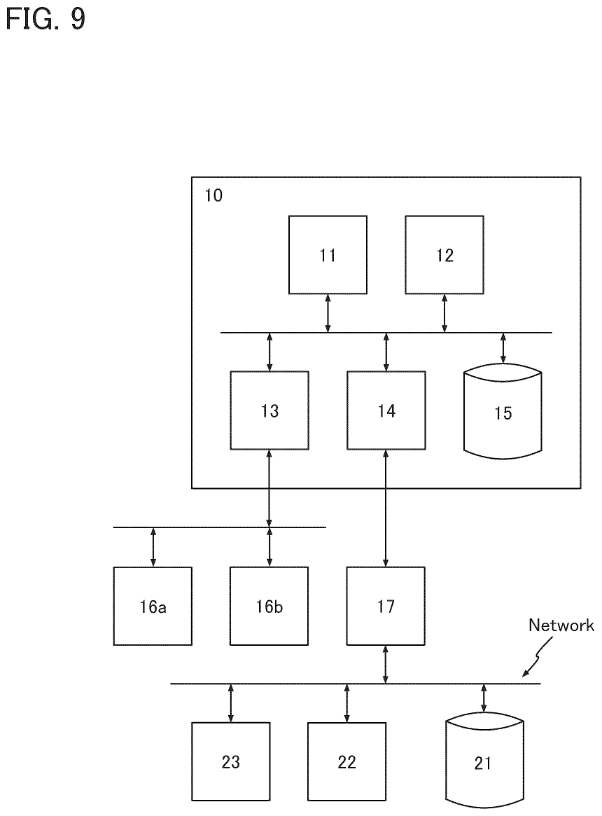

FIG. 9 is a diagram showing a computer for operating a program. A computer 10 connects a database 21 with a remote computer 22 or a remote computer 23 through a network (Network). The computer 10 includes an arithmetic unit 11, a memory 12, an input/output interface 13, a communication device 14, and a storage 15. The computer 10 is electrically connected to a display device 16a and a keyboard 16b through the input/output interface 13. In addition, the computer 10 is electrically connected to a network interface 17 through the communication device 14, and the network interface 17 is electrically connected to the database 21, the remote computer 22, and the remote computer 23 through the network.

The network includes a local area network (LAN) or the Internet. For the above network, wired or wireless communication or wired and wireless communication can be used.

In the case where wireless communication is used in the above network, a variety of communication methods can be used, for example, a near field communication method such as Wi-Fi (registered trademark) or Bluetooth (registered trademark), a communication method satisfying the third generation mobile communication system (3G) such as LTE (also referred to as 3.9G in some cases), a communication method satisfying the fourth generation mobile communication system (4G), and a communication method satisfying the fifth generation mobile communication system (5G).

In the method for predicting electrical characteristics of a semiconductor element of one embodiment of the present invention, the computer 10 is used for predicting the electrical characteristics of the semiconductor element. A program of the computer 10 is stored in the memory 12 or the storage 15. The program generates a learning model using the arithmetic unit 11. The program can be displayed on the display device through the input/output interface 13. A user can supply learning data such as a process list, electrical characteristics, a schematic cross-sectional view, a cross-sectional observation image, or the like from a keyboard with respect to the program displayed on the display device 16a. The electrical characteristics of the semiconductor element, which are predicted by the method for predicting electrical characteristics of a semiconductor element, are converted into numbers, formulae, or graphs and displayed by the display device 16a.

Note that the program can also be utilized in the remote computer 22 or the remote computer 23 through the network. Alternatively, the program can be activated by the computer 10 with a program stored in a memory or a storage of the database 21, the remote computer 22, or the remote computer 23. The remote computer 22 may be a portable information terminal or a portable terminal such as a tablet computer or a laptop computer. In the case of a portable information terminal, a portable terminal, or the like, communication can be performed using wireless communication.

Hence, according to one embodiment of the present invention, a method for predicting electrical characteristics of a semiconductor element, with use of a computer, can be provided. In the method for predicting electrical characteristics of a semiconductor element, multimodal learning can be performed by supply of learning data such as a process list, the electrical characteristics of the semiconductor element generated in accordance with the process list, or a schematic cross-sectional view or cross-sectional observation image of the semiconductor element generated in accordance with the process list. Furthermore, in the method for predicting electrical characteristics of a semiconductor element, the electrical characteristics of the semiconductor element or values of variables in a formula representing the electrical characteristics can be predicted by supply of inference data such as a new process list, conditions of voltages applied to the semiconductor element, a schematic cross-sectional view, or a cross-sectional observation image. For example, in the case of adding a new step to the process list, the electrical characteristics of a transistor can be easily predicted. Therefore, with the method for predicting electrical characteristics of a semiconductor element of one embodiment of the present invention, the number of demonstrations in the development of the semiconductor element can be reduced, and the past demonstration information can be effectively used.

Parts of this embodiment can be combined as appropriate for implementation.

### REFERENCE NUMERALS

OUT_w: output terminal, OUT_1: output terminal, 10: computer, 11: arithmetic unit, 12: memory, 13: input/output interface, 14: communication device, 15: storage, 16a: display device, 16b: keyboard, 17: network interface, 21: database, 22: remote computer, 23: remote computer, 110: feature-value calculation portion, 110A: feature-value calculation portion, 110B: feature-value calculation portion, 110C: feature-value calculation portion, 120: feature prediction portion, 210: learning model, 211: neural network, 211a: input layer, 211b: hidden layer, 211c: hidden layer, 212: neural network, 212a: AGGREGATE layer, 212b: fully connected layer, 212c: fully connected layer, 220: learning model, 221: neural network, 230: learning model, 231: connected layer, 231A: connected layer, 232: fully connected layer, 233: fully connected layer, 240: learning model, 241: neural network, 241a: convolutional layer, 241e: convolutional layer, 242: fully connected layer, 242a: fully connected layer, 242c: fully connected layer

1. A method for predicting electrical characteristics of a semiconductor element comprising the steps of:
inputting a process list for generating the semiconductor element to a first learning model and generating a first feature value from the first learning model;
inputting electrical characteristics of the semiconductor element formed in accordance with the process list to a second learning model and generating a second feature value from the second learning model;
inputting image data of the semiconductor element formed in accordance with the process list to a third learning model and generating a third feature value from the third learning model;
performing multimodal learning in a fourth learning model using the first feature value, the second feature value, and the third feature value;
outputting predicted electrical characteristics of the semiconductor element from the fourth learning model; and
displaying at least one of numbers, formulae, and graphs converted from the predicted electrical characteristics of the semiconductor element.

2. The method according to claim 1,
wherein the process list comprises a plurality of process items for forming the semiconductor element, and
wherein each of the plurality of process items includes a code representing a type of process and a type of equipment used in the process, and conditions given to the code.

3. The method according to claim 1,
wherein the image data is at least one of a schematic cross-sectional view and a cross-sectional observation image of the semiconductor element formed in accordance with the process list.

4. The method according to claim 1,
wherein the semiconductor element is a transistor, and
wherein the predicted electrical characteristics are selected from a field-effect mobility of the transistor, a capacitance per unit area of a gate insulating film of the transistor, a channel length of the transistor, a channel width of the transistor, and a threshold voltage of the transistor.

5. The method according to claim 4,
wherein the transistor comprises a metal oxide in a semiconductor layer.

6. The method according to claim 1,
wherein the first learning model comprises a first neural network,
wherein the second learning model comprises a second neural network, and
wherein the method further comprises a step of updating a weight coefficient of the second neural network by the first feature value.

7. A system for predicting electrical characteristics of a semiconductor element, the system comprising a computer and a display device,
wherein the computer is configured to:
input a process list for generating the semiconductor element to a first learning model;
generate a first feature value from the first learning model;
input electrical characteristics of the semiconductor element formed in accordance with the process list to a second learning model;
generate a second feature value from the second learning model;
input image data of the semiconductor element formed in accordance with the process list to a third learning model;
generate a third feature value from the third learning model;
perform multimodal learning in a fourth learning model using the first feature value, the second feature value, and the third feature value; and
output predicted electrical characteristics of the semiconductor element from the fourth learning model, and
wherein the display device is configured to display at least one of numbers, formulae, and graphs converted from the predicted electrical characteristics of the semiconductor element.

8. The system according to claim 7,
wherein the process list comprises a plurality of process items for forming the semiconductor element, and
wherein each of the plurality of process items includes a code representing a type of process and a type of equipment used in the process, and conditions given to the code.

9. The system according to claim 7,
wherein the image data is at least one of a schematic cross-sectional view and a cross-sectional observation image of the semiconductor element formed in accordance with the process list.

10. The system according to claim 7,
wherein the semiconductor element is a transistor, and
wherein the predicted electrical characteristics are selected from a field-effect mobility of the transistor, a capacitance per unit area of a gate insulating film of the transistor, a channel length of the transistor, a channel width of the transistor, and a threshold voltage of the transistor.

11. The system according to claim 10,
wherein the transistor comprises a metal oxide in a semiconductor layer.

12. The system according to claim 7,
wherein the first learning model comprises a first neural network,
wherein the second learning model comprises a second neural network, and
wherein the method further comprises a step of updating a weight coefficient of the second neural network by the first feature value.
